(19) United States
(12) Patent Application Publication
(10) Pub. No.: US 2013/0078806 A1
(43) Pub. Date: Mar. 28, 2013

(54) Method for Fabricating Copper Interconnections in an Ultra Low Dielectric Constant Film

(71) Applicants: Yuwen Chen, Shanghai (CN); Qiang Xu, Shanghai (CN); Chunsheng Zheng, Shanghai (CN); Wenguang Zhang, Shanghai (CN)

(72) Inventors: Yuwen Chen, Shanghai (CN); Qiang Xu, Shanghai (CN); Chunsheng Zheng, Shanghai (CN); Wenguang Zhang, Shanghai (CN)

(73) Assignee: SHANGHAI HUALI MICROELECTRONICS CORPORATION, Shanghai (CN)

(21) Appl. No.: 13/339,736

(22) Filed: Dec. 29, 2011

(30) Foreign Application Priority Data
Sep. 28, 2011 (CN) 201110298516.5

(51) Int. Cl. H01L 21/768

(52) U.S. Cl. 438/675; 257/E21.585

(57) ABSTRACT

The invention relates to a method for fabricating copper interconnections in an ultra low dielectric constant film, comprising the following steps of: depositing an etching stop layer on a silicon wafer, depositing an ultra-low-k film on the etching stop layer, and depositing a SiO₂-riched layer on the ultra-low-k film; forming a via and/or trench that penetrates through the SiO₂-riched layer and the ultra-low-k film by using a photo-lithography and etching process; sputter-depositing a metal barrier layer and a copper seed crystal layer within the via and/or trench, performing a copper filling deposition by an electroplating process, performing a chemical mechanical polishing until the SiO₂-riched layer is reached, whereby forming a copper interconnection layer. Since the SiO₂-riched layer and the ultra-low-k film can be deposited in the same tool, this method has the , advantages of shortening the production period, lowering the production cost and improving the adhesion in the copper interconnection structure.

### CROSS REFERENCE TO THE RELATED APPLICATIONS

This application is based upon and claims the benefit of priority from the prior Chinese Patent Application No. 201110298516.5 filed on Sep. 28, 2011, entitled “A Method for Fabricating Copper Interconnections in An Ultra Low Dielectric Constant Film” with Chinese State Intellectual Property Office, under 35 U.S.C. §119. The contents of the above prior Chinese Patent Application are incorporated herein by reference in its entirety.

### TECHNICAL FIELD

The present invention relates to the semiconductor technology, and more particularly to a method for fabricating copper interconnections in an ultra low dielectric constant film.

### BACKGROUND

With increasing progress of the process technology of ultra-large scale integration (ULSI) circuits, the characteristic dimensions of semiconductor devices are reduced gradually and the chip area is continually increased, the delay time of interconnection lead has already been comparable with the gate delay time of a device. The people are now faced with a problem of how to overcome significant increase of RC (in which “R” refers to “resistance” and “C” refers to “capacitance”) delay resulting from sharp increase of connection length. Particularly, as the impact of wire to wire capacitance of metal wiring becomes increasingly serious, performances of the devices have been degraded substantially, which has become a critical limiting factor in further development of semiconductor industry. Now, various measures have been taken in order to reduce the RC delay caused by the interconnection.

The parasitic capacitance and the interconnection resistance between interconnections cause a transmission delay of signal. As copper (Cu) with lower electric resistivity, superior anti-electromigration property and high reliability can reduce the metal interconnection resistance and thus reduce the overall interconnection delay, the conventional aluminum interconnection has been changed into a low-resistance copper interconnection now. Meanwhile, the delay can be also decreased as the decrease of the capacitance between the interconnections, and the parasitic capacitance C is in positive proportion to the relative dielectric constant k of the circuit layer insulating medium, so that it is necessary to use material with low k as insulating medium of different circuit layers to take in place of conventional SiO₂ medium, for satisfying development of high-speed chip.

The RC delay in the interconnection layer is the main important factor for limiting the speed of integration circuit. In order to reduce the parasitic capacitance between the metal interconnection layers, materials with low dielectric constant (low-k), even with ultra low dielectric constant (ultra-low-k) have been used in the prior art. And the materials with low dielectric constant and those with ultra low dielectric constant are generally made into porous and loose structures so as to reduce dielectric constants thereof. However, the porous and loose ultra-low-k film may encounter a series of problems in the fabricating process of interconnection layer; in comparison with a compact low-k film, the porous and loose ultra-low-k film has a lower mechanical property, so that moisture and dissolvent will easily permeate into the ultra-low-k film during the chemical mechanical polishing (CMP) and packaging. The ultra-large scale integration circuit in the prior art uses multi-level interconnection layers, in which it is usually adopted that an oxide hard mask is deposited on the ultra-low-k film, whereas the deposition of the oxide hard mask needs to be done in a tool (device) that is separated from another tool for making the ultra-low-k film. This will result in a prolonged production period and an increased production cost. Meanwhile, in the subsequent chemical mechanical polishing, the polishing is controlled to be performed on the ultra-low-k film, but the adhesion is very poor between the ultra-low-k film and an etching stop layer of next interconnection layer.

### SUMMARY OF THE INVENTION

It is an object of the present invention to provide a method for fabricating copper interconnections in an ultra low dielectric constant film in order to shorten the production period, lower the production costs and improve the adhesion in the copper interconnection structures.

The invention provides a method for fabricating copper interconnections in an ultra low dielectric constant film, comprising the following steps of:

depositing an etching stop layer on a silicon wafer, depositing an ultra-low-k film on the etching stop layer, and depositing a SiO₂-riched layer on the ultra-low-k film;

forming a via and/or trench that penetrates through the SiO₂-riched layer and the ultra-low-k film by using a photo-lithography and etching process; and

sputter-depositing a metal barrier layer and a copper seed crystal layer in the via and/or trench, performing a copper filling deposition by an electroplating process, and performing a chemical mechanical polishing until the SiO₂-riched layer is reached, whereby forming a copper interconnection layer.

Preferably, the photo-lithography and etching process is used in the method to form a via and a trench that penetrate through the SiO₂-riched layer and the ultra-low-k film, and the step of forming a via and trench that penetrate through the SiO₂-riched layer and the ultra-low-k film by using a photo-lithography and etching process comprises the following steps of:

depositing a metal hard mask on the SiO₂-riched layer, depositing a first bottom anti-reflection coating layer on the metal hard mask, coating a photoresist on the first bottom anti-reflection coating layer and forming a first etching window by ₚhoto-lithography; etching the first bottom anti-reflection coating layer and the metal hard mask within the first etching window until the SiO₂-riched layer is ᵣeached, removing the photoresist and the first bottom anti-reflection coating layer to form a second etching window in the metal hard mask, the second etching window being served as a window for etching a trench in the subsequent step(s);depositing a second bottom anti-reflection coating layer on the surface of the above structure, coating a photoresist on the second bottom anti-reflection coating layer and forming a third etching window by photo-lithography, the third etching window being served as the window for etching a via in the subsequent step(s), the position of the third etching window being corresponding to that of the second etching window, and the size of the third etching window being less than or equal to the second etching window;

etching the second bottom anti-reflection coating layer, the SiO₂-riched layer and a part of the ultra-low-k film within the third etching window to form a semi-finished via with a blind bottom (i.e., a blind hole), removing the photoresist and the second bottom anti-reflection coating layer to expose the second etching window; and

etching the SiO₂-riched layer and a part of the ultra-low-k film within the second etching window to form a trench, during the etching process, synchronously etching the ultra-low-k film and the etching stop layer beneath the semi-finished via, so as to form the via (i.e. through hole).

Preferably, the photo-lithography and etching process is used in the method to form a via or trench that penetrates through the SiO₂-riched layer and the ultra-low-k film, and the step of forming a via or trench that penetrates through the SiO₂-riched layer and the ultra-low-k film by using a photo-lithography and etching process comprises the following steps of:

depositing a metal hard mask on the SiO₂-riched layer, depositing a bottom anti-reflection coating layer on the metal hard mask, coating a photoresist on the bottom anti-reflection coating layer and forming a first etching window by photo-lithography;

etching the bottom anti-reflection coating layer and the metal hard mask within the first etching window until the SiO₂-riched layer is reached, and remₒving the photoresist and the bottom anti-reflection coating layer to form a second etching window in the metal hard mask, the second etching window being served as a window for etching a via or trench in the subsequent step(s); and

etching the SiO₂-riched layer, the ultra-low-k film and the etching stop layer within the second etching window to form the via or trench.

Preferably, the etching stop layer may be made of SiN, SiC, SiOC, SiOCN or SiCN.

Preferably, the SiO₂-riched layer may have a thickness of 500-2500 Å.

Preferably, the ultra-low-k film may be formed by using an organic polymer spin-on coating process or by using a CVD process based on SiO₂ material, and the ultra-low-k film may have a dielectric constant of 2.2-2.8.

Preferably, the ultra-low-k film may have a thickness of 2000-5000 Å.

Preferably, the metal hard mask may be made of Ta, Ti, W, TaN, TIN or WN.

As compared with the prior art, after deposition of the ultra-low-k film, the SiO₂-riched layer is deposited in the same tool in this invention, so that the production period can be shortened and the production cost can also be lowered. Meanwhile, a part of SiO₂-riched layer can be remained after the chemical mechanical polishing process of the copper interconnection preparation, and the SiO₂-riched layer increases the adhesion between the ultra-low-k film and an etching stop layer of next copper interconnection, so that the situation of delamination can be easily prevented from.

### BRIEF DESCRIPTION OF THE DRAWINGS

FIG. 1 is a flow chart of fabricating process of the present invention.

FIGS. 2a-2i are cross-sections illustrating the process steps in a fabricating process of one embodiment of the invention.

FIGS. 3a-3f are cross-sections illustrating the process steps in a fabricating process of another embodiment of the invention.

### DETAILED DESCRIPTION OF THE EMBODIMENTS

Hereinafter, the present invention will be further described in details with reference to the appended drawings.

In the following description, many of details are illustrated in order to make a full comprehension of the present invention. However, the invention can be implemented in other ways that differ from those described herein, and modifications and variations can be made by the person skilled in the art without departing from the spirit of the invention. Thus, the present invention shall not be restricted by the embodiments disclosed below.

In addition, the present invention is described herein with reference to the schematic drawings, and in the expatiation of the embodiments of the invention, the cross-sections for representing the structure of the device do not comply with the common ratio to be partially enlarged, for the sake of convenient explanation. Moreover, these schematic drawings are illustrated only as examples and should not be as limitations to the protection scope of the invention. Furthermore, during practical fabricating, each structure shown in the drawings should be embodied in a three-dimensional space and have length, width and depth.

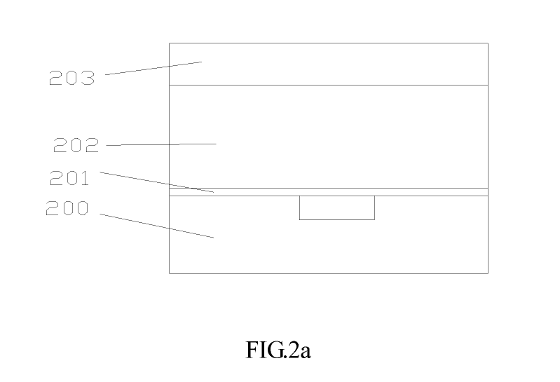

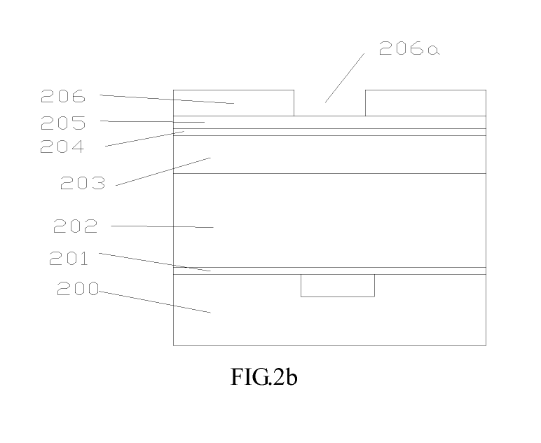

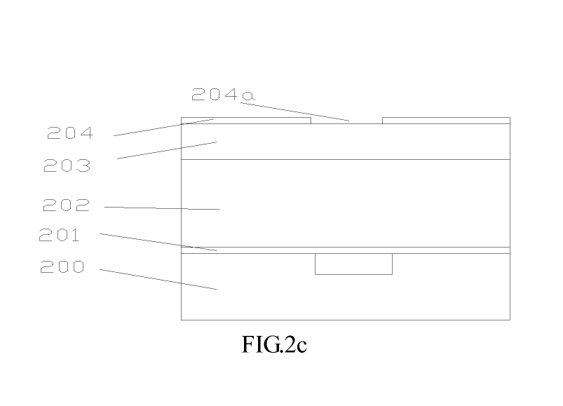

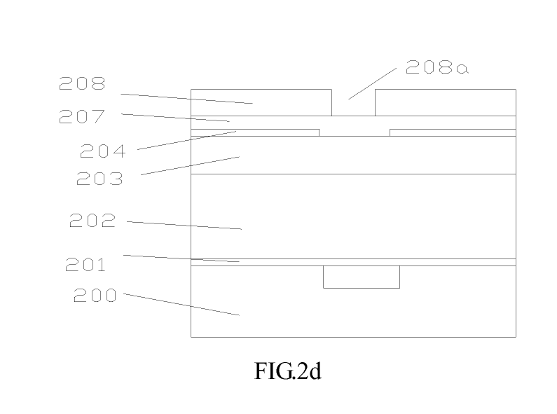

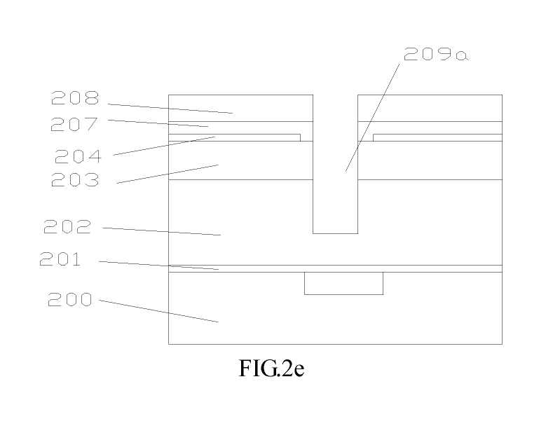

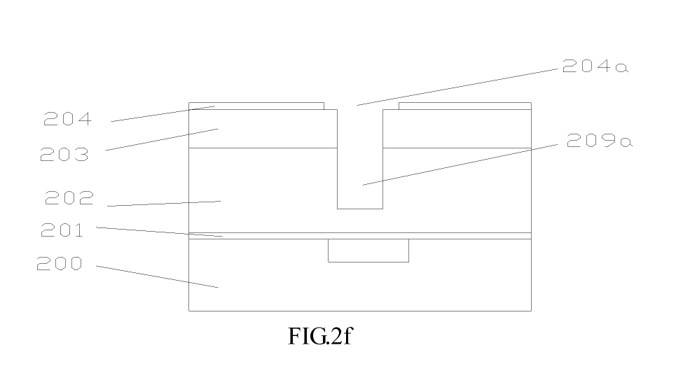

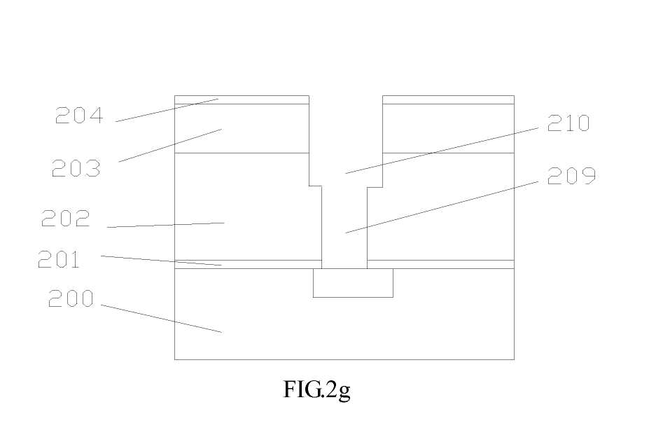

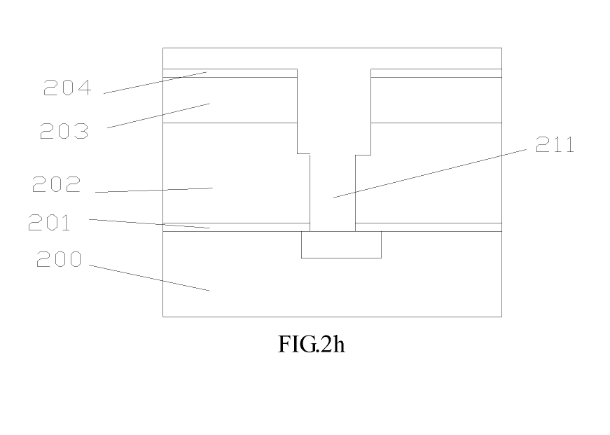

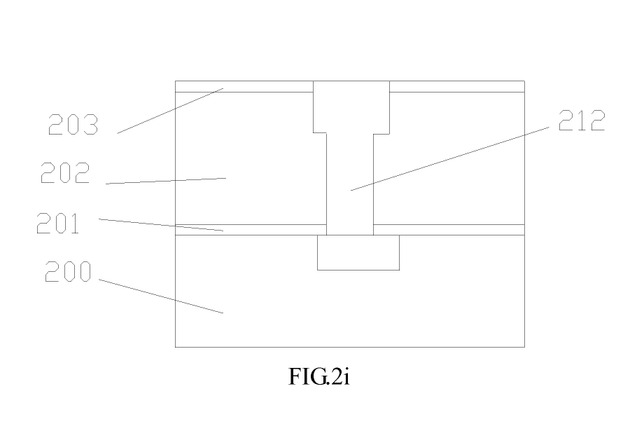

FIGS. 2a-2i illustrate an embodiment of the invention. In this embodiment, a silicon wafer is firstly provided, which has at least one interconnection layer formed on its surface, and then it is needed to form a via and a trench in sequence on a front-layer interconnection layer (i.e. a bottom interconnection layer) of the surface of silicon wafer by means of the steps described below. To simplify the diagrammatic presentation, the structure of the silicon wafer beneath the front-layer interconnection layer will be omitted in FIGS. 2a-2i.

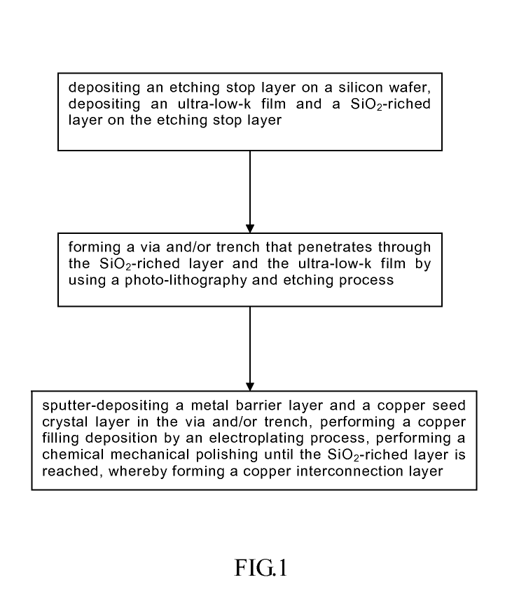

As shown in FIG. 1, the fabricating process for copper interconnections in the ultra low dielectric constant (ultra-low-k) film will be described as follows.

In step 1, as shown in FIG. 2, an etching stop layer 201 is deposited on a silicon wafer 200, and an ultra-low-k film 202 and a SiO₂-riched layer 203 are deposited on the etching stop layer 201, in which the ultra-low-k film 202 and the SiO₂-riched layer 203 are made in the same tool. The SiO₂-riched layer can take in place of the oxide hard mask in the prior art, which is deposited in a tool different from a tool for making the ultra-low-k film 202. Thus, the production period can be shortened and the production costs can be reduced. The SiO₂-riched layer has a thickness of 500-2500 Å. The etching stop layer 201 can be made of SiN, SiC, SiOC, SiOCN or SiCN. The ultra-low-k film 202 is formed by using an organic polymer spin-on coating process or by using a CVD process based on SiO₂ material. The ultra-low-k film 202 has a thickness of 2000-5000 Å. The ultra-low-k film has a dielectric constant of 2.2-2.8.

In step 2, a via and a trench that penetrate through the SiO₂-riched layer 203 and the ultra-low-k film 202 are formed by using a photo-lithography and etching process. Hereinafter, the details of this step will be described.

As shown in FIG. 2b, a metal hard mask 204 is deposited on the SiO₂-riched layer 203, and the metal hard mask is made of Ta, Ti, W, TaN, TIN or WN. Next, a first bottom anti-reflection coating layer 205 is deposited on the metal hard mask 204, a photoresist 206 is coated on the first bottom anti-reflection coating layer 205, and a first etching window 206a is formed by photo-lithography. Further, as shown in FIG. 2c, etching is applied to the first bottom anti-reflection coating layer 205 and the metal hard mask 204 within the first etching window 206a, until the SiO₂-riched layer 203 is reached. Then, the photoresist 206 and the first bottom anti-reflection coating layer 205 are removed to form a second etching window 204a in the metal hard mask 204, which serves as a window for etching a trench in the subsequent step(s).

As shown in FIG. 2d, a second bottom anti reflection coating layer 207 is deposited on a surface of the above structure (resulted structure or formed structure), a photoresist 208 is coated on the second bottom anti-reflection coating layer 207, and a third etching window 208a is formed by photo-lithography. The third etching window 208a can be served as a window for etching a via in the subsequent step(s), the position of which corresponds to the position of the second etching window 204a, and the size of which is less than or equal to the second etching window 204a.

As shown in FIG. 2e, etching is applied to the second bottom anti-reflection coating layer 207, the SiO₂-riched layer 203 and a part of the ultra-low-k film 202 within the third etching window 208a, so as to form a semi-finished via 209a with a blind bottom. Furthermore, as shown in FIG. 2f, the photoresist 208 and the second bottom anti-reflection coating layer 207 are removed to expose the second etching window 204a.

As shown in FIG. 2g, etching is performed to the SiO₂-riched layer 203 and a part of the ultra-low-k film 202 within the second etching window 204a, so as to form a trench 210. During the etching process, etching is synchronously applied to the ultra-low-k film 202 and the etching stop layer 201 beneath the semi-finished via 209a with a blind bottom, so as to form the via 209.

In step 3, as shown in FIG. 2h, a metal barrier layer and a copper seed crystal layer are sputter-deposited within the via 209 and the trench 210, and a copper filling deposition is applied by an electroplating process to form a metal layer 211. As shown in FIG. 2i, the metal layer 211 on the SiO₂-riched layer 203 and the metal hard mask 204 are removed by a chemical mechanical polishing. Such polishing is stopped on the SiO₂-riched layer 203. After this polishing step, the remained SiO₂-riched layer 203 has a thickness of 50-150 Å, whereby a copper interconnection structure 212 is formed. The remained SiO₂-riched layer 203 will increase the adhesion between the ultra-low-k film and an etching stop layer of next copper interconnection.

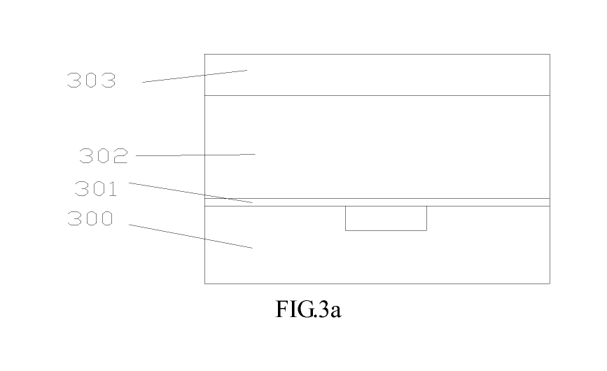

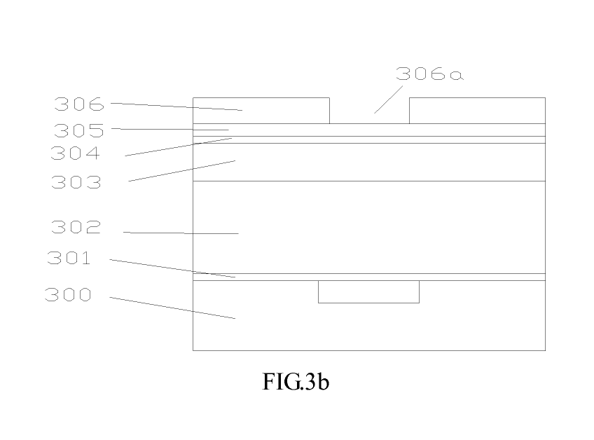

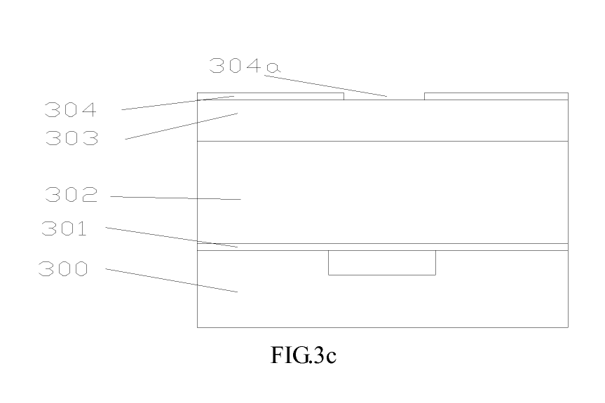

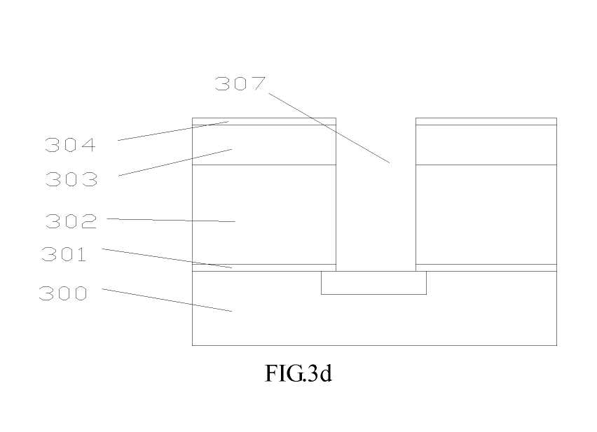

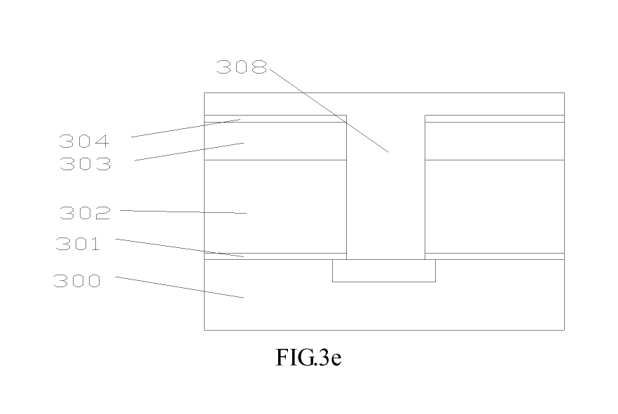

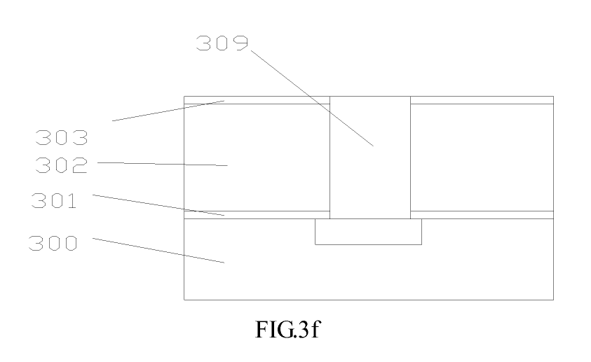

FIGS. 3a-3f illustrate another embodiment of the invention. In this embodiment, a silicon wafer is firstly provided which has at least one interconnection layer formed on its surface, and then it is needed to form a via or a trench on the front-layer interconnection layer of the surface of the silicon wafer by means of the steps described below. To simplify the diagrammatic presentation, the structure of the silicon wafer beneath the front-layer interconnection layer will be omitted in FIGS. 3a-3f.

The fabricating process of another embodiment of the invention will be described as follows. In step 1, as shown in FIG. 3a, an etching stop layer 301 is deposited on an upper interconnection layer 300, and an ultra-low-k film 302 and a SiO₂-riched layer 303 are deposited on the etching stop layer 301. The SiO₂-riched layer 303 can take in place of the oxide hard mask in the prior art, which is deposited in a tool different from a tool for making the ultra-low-k film 302. Thus, the production period can be shortened and the production costs can be reduced. The SiO₂-riched layer has a thickness of 500-2500 Å. The etching stop layer 301 can be made of SiN, SiC, SiOC, SiOCN or SiCN. The ultra-low-k film 302 is formed by using an organic polymer spin-on coating process or by using a CVD process based on SiO₂ material. The ultra-low-k film 302 has a thickness of 2000-5000 Å. The ultra-low-k film 302 has a dielectric constant of 2.2-2.8.

In step 2, a via or trench that penetrates through the SiO₂-riched layer 303 and the ultra-low-k film 302 is formed by using a photo-lithography and etching process. Hereinafter, the details of this step will be described.

As shown in FIG. 3b, a metal hard mask 304 is deposited on the SiO₂-riched layer 303, and the metal hard mask 304 is made of Ta, Ti, W, TaN, TiN or WN. Next, a bottom anti-reflection coating layer 305 is deposited on the metal hard mask 304, a photoresist 306 is coated on the bottom anti-reflection coating layer 305 and a first etching window 306a is formed by photo-lithography. Further, as shown in FIG. 3c, etching is applied to the bottom anti-reflection coating layer 305 and the metal hard mask 304 within the first etching window 306a until the SiO₂-riched layer 303 is reached. Then, the photoresist 306 and the bottom anti-reflection coating layer 305 are removed to form a second etching window 304a in the metal hard mask 304, which serves as a window for etching a trench or via in the subsequent step(s).

As shown in FIG. 3d, etching is applied to the SiO₂-riched layer 303, the ultra-low-k film 302 and the etching stop layer 301 within the second etching window 304a, so as to form the via or trench 307 connected with the front-layer interconnection layer.

In step 3, as shown in FIG. 3e, a metal barrier layer and a copper seed crystal layer are sputter-deposited in the via or trench 307, and a copper filling deposition is applied by an electroplating process to form a metal layer 308. Further, as shown in FIG. 3f, the metal layer 308 on the SiO₂-riched layer 303 and the metal hard mask 304 are removed by a chemical mechanical polishing. Such polishing is stopped on the SiO₂-riched layer 303. After this polishing step, the remained SiO₂-riched layer 303 has a thickness of 50-150 Å, whereby a copper interconnection structure 309 is formed. The remained SiO₂-riched layer 303 will increase the adhesion between the ultra-low-k film and the etching stop layer of the next copper interconnection.

Although the via(s) and/or trench(s) are formed in the front-layer interconnection layer in accordance with the above-mentioned embodiments of the present invention, the invention will be not limited thereto. In addition, the via(s) and/or trench(s) can be arranged directly on the device layer of the surface of the silicon wafer, or the invention can be applied to other structures similar to the via or trench.

The above disclosure should be construed as merely describing preferable embodiments of the present invention, and all the equivalent variations and modifications made in terms of the scope claimed by the invention should be understood as falling within the scope of the attached claims.

1. A method for fabricating copper interconnections in an ultra low dielectric constant film, comprising the following steps of:
depositing an etching stop layer on a silicon wafer, depositing an ultra-low-k film on the etching stop layer, and depositing a SiO₂-riched layer on the ultra-low-k film;
forming a via and/or trench that penetrates through the SiO₂-riched layer and the ultra-low-k film by using a photo-lithography and etching process; and
sputter-depositing a metal barrier layer and a copper seed crystal layer in the via and/or trench, performing a copper filling deposition by an electroplating process, performing a chemical mechanical polishing until the SiO₂-riched layer is reached, whereby forming a copper interconnection layer.

2. The method for fabricating copper interconnections in an ultra low dielectric constant film in accordance with claim 1, wherein the photo-lithography and etching process is used in the method to form a via and a trench that penetrate through the SiO₂-riched layer and the ultra-low-k film, and the step of forming a via and a trench that penetrate through the SiO₂-riched layer and the ultra-low-k film by using the photo-lithography and etching process comprises the following steps of:
depositing a metal hard mask on the SiO₂-riched layer, depositing a first bottom anti-reflection coating layer on the metal hard mask, coating a photoresist on the first bottom anti-reflection coating layer and forming a first etching window by photo-lithography, etching the first bottom anti-reflection coating layer and the metal hard mask within the first etching window until the SiO₂-riched layer is reached, removing the photoresist and the first bottom anti-reflection coating layer to form a second etching window in the metal hard mask which is served as a window for etching the trench in the subsequent step(s);
depositing a second bottom anti-reflection coating layer on a surface of the resulted structure, coating a photoresist on the second bottom anti-reflection coating layer and forming a third etching window by photo-lithography, which is served as a window for etching in the subsequent step(s), the position of which corresponds to the position of the second etching window, and the size of which is less than or equal to the second etching window;
etching the second bottom anti-reflection coating layer, the SiO₂-riched layer and a part of the ultra-low-k film within the third etching window to form a semi-finished via with a blind bottom, and removing the photoresist and the second bottom anti-reflection coating layer to expose the second etching window; and
etching the SiO₂-riched layer and a part of the ultra-low-k film within the second etching window to form a trench, during the etching process, synchronously etching the ultra-low-k film and the etching stop layer beneath the semi-finished via, so as to form the via.

3. The method for fabricating copper interconnections in an ultra low dielectric constant film in accordance with claim 1, wherein the photo-lithography and etching process is used in the method to form a via or trench that penetrates through the SiO₂-riched layer and the ultra-low-k film, and the step of forming a via or trench that penetrates through the SiO₂-riched layer and the ultra-low-k film by using a photo-lithography and etching process comprises the following steps of:
depositing a metal hard mask on the SiO₂-riched layer, depositing a bottom anti-reflection coating layer on the metal hard mask, coating a photoresist on the bottom anti-reflection coating layer and forming a first etching window by photo-lithography;
etching the bottom anti-reflection coating layer and the metal hard mask within the first etching window until the SiO₂-riched layer is reached, and removing the photoresist and the bottom anti-reflection coating layer to form a second etching window in the metal hard mask, the second etching window being served as a window for etching the via or trench in the subsequent step(s); and
etching the SiO₂-riched layer, the ultra-low-k film and the etching stop layer within the second etching window to form the via or trench.

4. The method for fabricating copper interconnections in an ultra low dielectric constant film in accordance with claim 1, wherein the etching stop layer is made of SiN, SiC, SiOC, SiOCN or SiCN.

5. The method for fabricating copper interconnections in an ultra low dielectric constant film in accordance with claim 1, wherein the SiO₂-riched layer has a thickness of 500-2500 Å.

6. The method for fabricating copper interconnections in an ultra low dielectric constant film in accordance with claim 1, wherein the ultra-low-k film is formed by using an organic polymer spin-on coating process or by using a CVD process based on SiO₂ material, and the ultra-low-k film has a dielectric constant of 2.2-2.8.

7. The method for fabricating copper interconnections in an ultra low dielectric constant film in accordance with claim 1, wherein the ultra-low-k film has a thickness of 2000-5000 Å.

8. The method for fabricating copper interconnections in an ultra low dielectric constant film in accordance with claim 2, wherein the metal hard mask is made of Ta, Ti, W, TaN, TiN or WN.

9. The method for fabricating copper interconnections in an ultra low dielectric constant film in accordance with claim 3, wherein the metal hard mask is made of Ta, Ti, W, TaN, TiN or WN.
